(19) United States
(12) Patent Application Publication
(10) Pub. No.: US 2026/0206204 A1
(43) Pub. Date: Jul. 16, 2026

(54) SEMICONDUCTOR DEVICE

(71) Applicant: Samsung Electronics Co., Ltd., Suwon-si (KR)

(72) Inventors: Jiseong AN, Suwon-si (KR); Tae-Jong LEE, Suwon-si (KR); Taewook KANG, Suwon-si (KR); Myeongjin BANG, Suwon-si (KR); Sunghyun CHOI, Suwon-si (KR)

(73) Assignee: Samsung Electronics Co., Ltd., Suwon-si (KR)

(21) Appl. No.: 19/362,658

(22) Filed: Oct. 20, 2025

(30) Foreign Application Priority Data
Jan. 14, 2025 (KR) 10-2025-0005458

(51) Int. Cl. H10B 12/00; H10D 1/68; H10D 62/10

(52) U.S. Cl. CPC H10B 12/30; H10D 1/714; H10D 62/126; H10B 12/03; H10B 12/05

(57) ABSTRACT

The present disclosure may provide a semiconductor device including a substrate, a first stacked structure comprising a plurality of semiconductor patterns on the substrate, the plurality of semiconductor patterns stacked and spaced from each other in a first direction, a first conductive pattern on a first side of the first stacked structure and extending in the first direction, and a plurality of data storage patterns on a second side of the first stacked structure, the plurality of data storage patterns spaced apart from each other in the first direction, and extending in a second direction, the second direction intersecting the first direction. A width of each of the plurality of semiconductor patterns in a third direction is greater than a width of each of the plurality of data storage patterns in the third direction, the third direction intersecting each of the first direction and the second direction.

### CROSS-REFERENCE TO RELATED APPLICATION

This application claims priority to Korean Patent Application No. 10-2025-0005458, filed in the Korean Intellectual Property Office on Jan. 14, 2025, the entire contents of which are hereby incorporated by reference.

### BACKGROUND

Example embodiments of the present disclosure relate to a semiconductor device.

As electronic products become more miniaturized, multifunctional, and provide increased performance, higher-capacity semiconductor devices are increasingly desired. Therefore, increased integration may be desired to provide higher-capacity semiconductor devices. Because the integration density of conventional two-dimensional semiconductor devices may be primarily determined by the area occupied by the unit cell, the integration density may be limited. Accordingly, a three-dimensional semiconductor device, which increases memory capacity by stacking a plurality of cells vertically on a substrate, is being proposed.

### SUMMARY

Some example embodiments of the present disclosure provide a semiconductor device with improved electrical characteristics and/or increased integration density.

Some example embodiments of the present disclosure are not limited to the above, and other variations of the example embodiments not explicitly described herein may be clearly understood by those skilled in the art from the description of the present disclosure.

According to some example embodiments of the present disclosure, a semiconductor device may include a substrate, a first stacked structure comprising a plurality of semiconductor patterns on the substrate, the plurality of semiconductor patterns stacked and spaced from each other in a first direction, a first conductive pattern on a first side of the first stacked structure and extending in the first direction, and a plurality of data storage patterns on a second side of the first stacked structure, the plurality of data storage patterns spaced apart from each other in the first direction, and extending in a second direction, the second direction intersecting the first direction. A width of each of the plurality of semiconductor patterns in a third direction is greater than a width of each of the plurality of data storage patterns in the third direction, the third direction intersecting each of the first direction and the second direction.

According to some example embodiments of the present disclosure, a semiconductor device may include a substrate, a first stacked structure comprising a plurality of semiconductor patterns on the substrate, the plurality of semiconductor patterns stacked and spaced apart from each other in a first direction, a first conductive pattern on a first side of the first stacked structure and extending in the first direction, a plurality of data storage patterns on a second side of the first stacked structure, the plurality of data storage patterns spaced apart from each other in the first direction and extending in a second direction, the second direction intersecting the first direction, a second stacked structure on the substrate and spaced apart from the first stacked structure in a third direction, the third direction intersecting each of the first direction and the second direction, and a support pattern between the first stacked structure and the second stacked structure. The support pattern comprises a first region and a second region, the second region extending from the first region in the second direction, and a depth of the first region in the first direction is smaller than a depth of the second region in the first direction.

According to some example embodiments of the present disclosure, a semiconductor device may include a substrate, a first stacked structure comprising a plurality of semiconductor patterns on the substrate, the plurality of semiconductor patterns stacked and spaced apart from each other in a first direction, a first conductive pattern on a first side of the first stacked structure and extending in the first direction, a plurality of data storage patterns on a second side of the first stacked structure, the plurality of data storage patterns spaced apart from each other in the first direction and extending in a second direction, the second direction intersecting the first direction, a second stacked structure on the substrate, the second stacked structure spaced apart from the first stacked structure in a third direction, the third direction intersecting each of the first direction and the second direction, and a support pattern between the first stacked structure and the second stacked structure. A width of each of the plurality of semiconductor patterns in the third direction is greater than a width of each of the plurality of data storage patterns in the third direction. The width of each of the plurality of semiconductor patterns in the third direction decreases toward the second side of the first stacked structure along the second direction. The support pattern comprises a first region and a second region, the second region extending from the first region in the second direction, and a depth of the first region in the first direction is smaller than a depth of the second region in the first direction.

According to some example embodiments of the present disclosure, a method for manufacturing a semiconductor device may include alternately stacking a plurality of sacrificial layers and a plurality of semiconductor layers on a substrate in a first direction, forming a plurality of through holes penetrating the plurality of sacrificial layers and the plurality of semiconductor layers to expose the substrate, forming a plurality of support patterns in the plurality of through holes, forming a plurality of trenches penetrating the plurality of sacrificial layers and the plurality of semiconductor layers to expose the substrate, removing the plurality of sacrificial layers, forming a plurality of semiconductor bars by partially removing each of the plurality of semiconductor layers in the first direction, forming a data storage pattern in a first trench among the plurality of trenches, and forming a first conductive pattern in a second trench among the plurality of trenches.

According to some example embodiments of the present disclosure, the plurality of through holes may include a first region and a second region extending in a second direction intersecting the first direction from the first region, and the forming of the plurality of through holes may include forming the plurality of through holes such that a width in a third direction intersecting each of the first direction and the second direction of the first region may be smaller than a width in the third direction of the second region.

According to some example embodiments of the present disclosure, the plurality of through holes may include a first region and a second region extending in a second direction intersecting the first direction from the first region, and the forming of the plurality of through holes may include forming the plurality of through holes such that a depth of the first region in the first direction may be smaller than a depth of the second region in the first direction.

According to some example embodiments of the present disclosure, the forming of the plurality of through holes may include forming the plurality of through holes such that the depth of the first region in the first direction may increase toward the second region.

According to some example embodiments of the present disclosure, before the forming of the data storage pattern in a first trench among the plurality of trenches, the method may further include partially removing each of the plurality of semiconductor bars in a second direction intersecting the first direction to form the data storage pattern.

According to some example embodiments of the present disclosure a method of manufacturing a semiconductor device my include forming a first stack pattern by alternately performing a first deposition process to form a plurality of sacrificial layers and a second deposition process to form a plurality of semiconductor layers stacked in a first direction on a substrate, forming a first mask layer on the first stack pattern, performing a first etch process on the first stack pattern to form a plurality of through holes, performing a third deposition process to form a plurality of support patterns in the plurality of through holes, forming a second mask layer on the plurality of support patterns and on the first mask layer, performing a second etch process to form a first trench, a second trench, and a lower pattern in the substrate between the first trench and the second trench, performing a third etch process to remove the plurality of sacrificial layers, performing a thinning process for forming a plurality of semiconductor bars by thinning each of the plurality of semiconductor layers in the first direction, and forming a plurality of first stack structures and data storage patterns between the plurality of semiconductor bars in the first direction.

According to some example embodiments of the present disclosure, in the performing the first etch process, each of the plurality of through holes may be formed to have a first region and a second region, wherein a depth of the first region in the first direction is smaller than a depth of the second region in the first direction, and the depth of the first region in the first direction increases toward the second region.

According to some example embodiments of the present disclosure, the integration density of a semiconductor device may be improved by increasing the spacing between horizontally adjacent data storage patterns.

According to some example embodiments of the present disclosure, a semiconductor device having improved electrical characteristics and/or reliability may be provided by increasing the separation distance between data storage patterns adjacent to each other in a horizontal direction.

The various beneficial advantages and effects of the present disclosure are not limited to the above-described contents, and will be more easily understood in the course of explaining the example embodiments of the present disclosure.

### BRIEF DESCRIPTION OF THE DRAWINGS

The above and other example embodiments and features of the present disclosure will become more apparent by describing in detail example embodiments thereof with reference to the attached drawings, in which:

FIG. 1 is an equivalent circuit diagram illustrating a cell array of a semiconductor device according to some example embodiments of the present disclosure;

FIG. 2 is a plan view illustrating a semiconductor device according to some example embodiments of the present disclosure;

FIG. 3 is a cross-sectional view taken along line B-B′ of FIG. 2;

FIG. 4 is a cross-sectional view taken along line C-C′ of FIG. 2;

FIGS. 5 to 17 are views illustrating intermediate steps of a method of manufacturing a semiconductor device according to some example embodiments of the present disclosure;

FIG. 18 is a plan view illustrating a semiconductor bar according to some example embodiments of the present disclosure; and

FIG. 19 is a cross-sectional view taken along line C-C′ of FIG. 16.

### DETAILED DESCRIPTION

With reference to the drawings below, semiconductor devices according to some example embodiments of the present disclosure will be described in detail. The example embodiments disclosed in this specification are exemplary example embodiments. Therefore, the present disclosure is not limited thereto and may be implemented in various other forms. Each of the example embodiments provided below is not excluded from being connected with one or more features of another example embodiment or other example embodiments that are consistent with the present disclosure but are not provided herein or within the present specification. For example, even if something described in a particular exemplary example embodiment is not described in another exemplary example embodiment, it may be understood that the feature relates to another of the exemplary example embodiments unless otherwise stated in the description. It should also be understood that all descriptions of principles, aspects and exemplary example embodiments are intended to include their structural and functional equivalents. Furthermore, it should be understood that these equivalents include not only the currently well-known equivalents but also the equivalents to be developed in the future, that is, all devices invented to perform the same function regardless of structure. For example, the material forming the contact or via may not be limited to the metals exemplified in this specification, provided that the present disclosure may be applied thereto.

When an element, component, layer, pattern, structure, region, etc. (hereinafter collectively referred to as a “component”) of a semiconductor device is referred to as being “over”, “above”, “on”, “below”, “under”, “beneath”, “connected to” or “coupled to” another component of the semiconductor device, it may be directly over, above, on, below, below, connected to, or coupled, or there may be intermediate components therebetween. In contrast, when one component of a semiconductor device is “directly over,” “directly above,” “directly on,” “directly below,” “directly under,” “directly beneath,” “directly beneath,” “directly connected to,” or “directly coupled to” another component of the semiconductor device, there are no intermediate components therebetween. Additionally, in this specification, the same drawing reference numerals may refer to the same components.

As used herein, spatially relative terms such as “over,” “above,” “on,” “upper,” “below,” “under,” “beneath,” “lower,” “top,” “bottom,” and the like may be used for convenience of explanation in describing the relationship of one component to another, as illustrated in the drawings. It will be understood that spatially relative terms are intended to encompass other orientations of the semiconductor device in use or operation in addition to the orientations depicted in the drawings. For example, if a semiconductor device is flipped in a drawing, a component described as “below” or “beneath” another component may be oriented “above” the other component, and the “top” or “upper” surface of a component may be the “bottom” or “lower” surface of the component. Thus, depending on the context, the term “below” may include both the upward and downward directions, and the term “top” may include both the top and the bottom. In this way, the semiconductor device may be oriented (rotated 90 degrees or otherwise) and the spatially relative descriptions used in the specification may be interpreted accordingly.

In the present disclosure, although the terms first, second, etc. are used to describe various elements or components, these elements or components are not limited by these terms. These terms should be understood as being used only to distinguish one element or component from another. It should be understood that the first element or component mentioned below may also be a second element or component within the technical spirit of the present disclosure.

With reference to the drawings below, a semiconductor device and a method for manufacturing the same according to some example embodiments of the present disclosure will be described in detail.

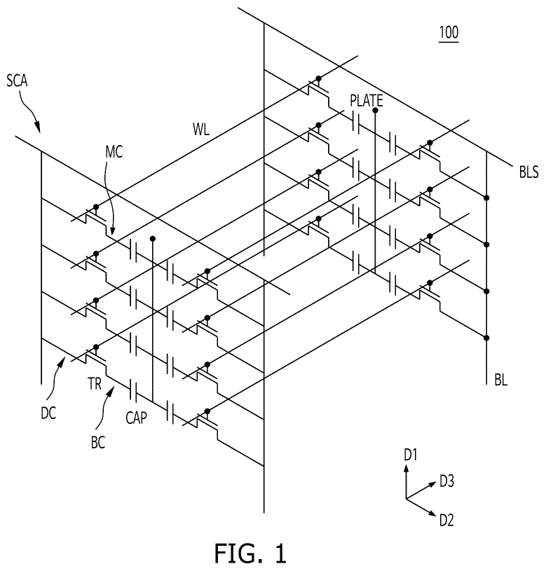

FIG. 1 is an equivalent circuit diagram showing a cell array of a semiconductor device according to some example embodiments of the present disclosure. Referring to FIG. 1, a semiconductor device 100 may include a plurality of memory cells MC configured with cell transistors TR and cell capacitors CAP that are disposed along a first direction D1 and a second direction D2 and connected to each other. A plurality of memory cells MC may be disposed in rows and spaced apart from each other along the first direction D1 and the third direction D3 to form a sub-cell array SCA. Here, the second direction D2 may be a direction intersecting (e.g., orthogonal to) the first direction D1. The third direction D3 may be a direction intersecting (e.g., orthogonal to) each of the first direction D1 and the second direction D2.

A semiconductor device 100 may have a plurality of sub-cell arrays SCA disposed spaced apart from each other along a third direction D3. A plurality of word lines WL may extend along a third direction D3 and be disposed spaced apart from each other along the first direction D1 and the second direction D2. A plurality of bit lines BL may extend along a first direction D1 and be disposed spaced apart from each other along each of a second direction D2 and a third direction D3.

Some of the plurality of bit lines BL may be connected to each other by a bit line strapping line BLS extending along the second direction D2. For example, the bit line strapping line BLS may connect bit lines BLs disposed along a second direction D2 among a plurality of bit lines BL.

A plurality of cell capacitors CAP may be commonly connected to an upper electrode PLATE extending in the first direction D1 and the third direction D3. For convenience of illustration, the upper electrode PLATE is illustrated as extending in the first direction D1, but the upper electrode PLATE disposed along the third direction D3 may form a single body.

The cell capacitors CAP and cell transistors TR disposed along the second direction D2 may be disposed to be mirror-symmetrical with respect to a plane extending in the first direction D1 perpendicular to the third direction D3, in which the upper electrode PLATE is disposed.

The cell transistor TR may be connected to the bit line BL via DC and to the cell capacitor CAP via BC.

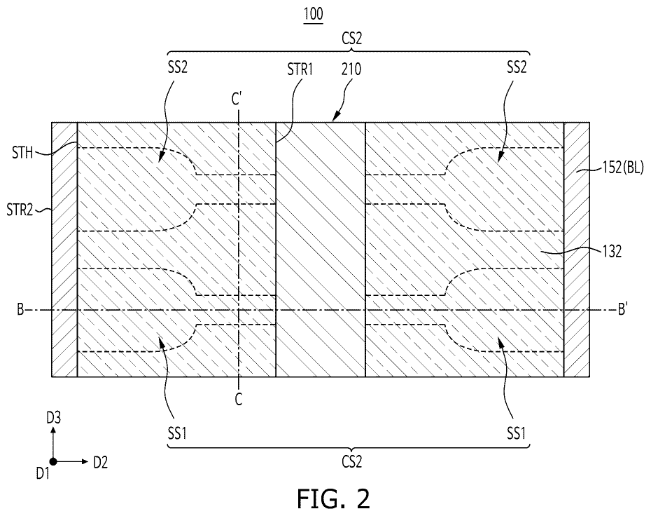

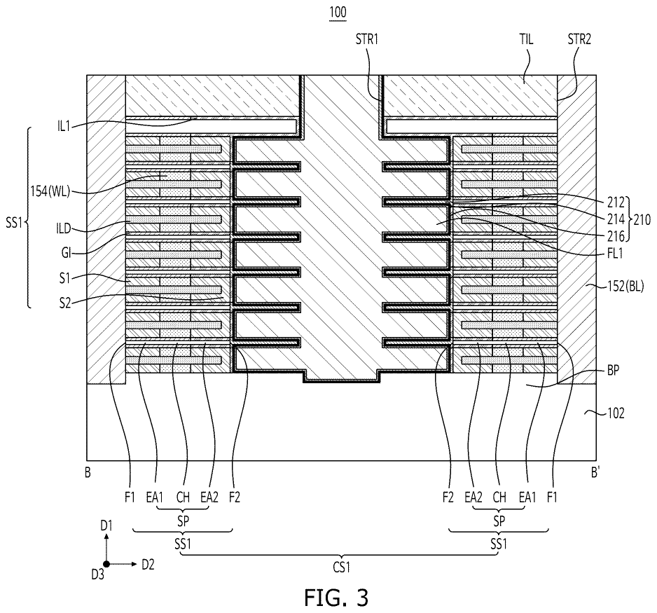

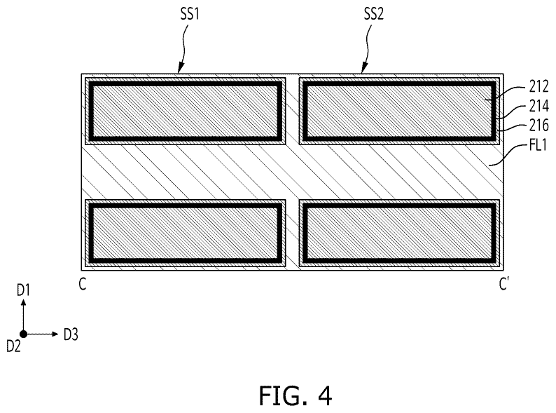

FIG. 2 is a plan view illustrating a semiconductor device according to some example embodiments of the present disclosure. FIG. 3 is a cross-sectional view taken along line B-B′ of FIG. 2. FIG. 4 is a cross-sectional view taken along line C-C′ of FIG. 2. Referring to FIGS. 2 to 4, a semiconductor device 100 according to some example embodiments of the present disclosure may include a substrate 102, a plurality of cell array structures CS1 and CS2, a plurality of first conductive patterns 152, a plurality of support patterns 132, and an upper insulating layer TIL.

The substrate 102 may include a semiconductor material, such as a group IV semiconductor, a group III-V compound semiconductor, or a group II-VI compound semiconductor. For example, a group IV semiconductor may include silicon, germanium, or silicon-germanium. The substrate 102 may further contain impurities. The substrate 102 may be a silicon substrate, a silicon-on-insulator SOI substrate, a germanium substrate, a germanium on insulator GOI substrate, a silicon-germanium substrate, or a substrate including an epitaxial layer. However, example embodiments are not limited thereto.

The first cell array structure CS1 may be disposed on a substrate 102. For example, the first cell array structure CS1 may be disposed on the substrate 102 along a direction perpendicular to the upper surface of the substrate 102. Here, the direction perpendicular to the upper surface of the substrate 102 may be referred to as the first direction D1. In some example embodiments, the first cell array structure CS1 may refer to the sub-cell array SCA illustrated in FIG. 1.

The first cell array structure CS1 may include a plurality of first stacked structures SS1 and a plurality of data storage patterns 210. A plurality of first stacked structures SS1 may be disposed on a lower pattern BP formed on a substrate 102. Each of the plurality of first stacked structures SS1 may be disposed spaced apart from each other in a second direction D2 intersecting the first direction D1.

A plurality of data storage patterns 210 may be disposed on a lower pattern BP formed on a substrate 102. Each of the plurality of data storage patterns 210 may be disposed spaced apart from each other in the first direction D1. A plurality of data storage patterns 210 may extend from the first stacked structure SS1 in the second direction D2. A plurality of data storage patterns 210 may be connected to the first stacked structure SS1.

A plurality of data storage patterns 210 may be disposed between first stacked structures SS1 that are adjacent to each other in the second direction D2 among a plurality of first stacked structures SS1. In some example embodiments, each of the plurality of first stacked structures SS1 may represent a cell transistor TR as illustrated in FIG. 1. In some example embodiments, each of the plurality of data storage patterns 210 may represent a cell capacitor CAP as illustrated in FIG. 1.

The first stacked structure SS1 may include a plurality of semiconductor patterns SP, a plurality of gate insulating layers GI, a plurality of interlayer insulating films ILDs, a plurality of second conductive patterns 154, a plurality of first spacers S1, a plurality of second spacers S2, and a plurality of first insulating liners IL1.

A plurality of semiconductor patterns SP may be disposed spaced apart from the substrate 102. Each of the plurality of semiconductor patterns SP may be disposed spaced apart from each other in the first direction D1. Here, each of the plurality of semiconductor patterns SP may overlap each other in the first direction D1. Each of the plurality of semiconductor patterns SP may extend in the second direction D2. Each of the plurality of semiconductor patterns SP may include a first edge portion EA1, a second edge portion EA2, and a channel portion CH. In some example embodiments, the thickness of a semiconductor pattern SP disposed at the top among a plurality of semiconductor patterns SP in the first direction D1 may be greater than the thickness of the remaining semiconductor patterns SP in the first direction D1. Among the plurality of semiconductor patterns SP, the semiconductor pattern SP disposed at the top may extend further in the second direction D2 than the remaining semiconductor patterns SP. For example, a semiconductor pattern SP disposed at the top among a plurality of semiconductor patterns SP may overlap with a data storage pattern 210 in the first direction D1.

The first edge portion EA1 and the second edge portion EA2 may be spaced apart from each other in the second direction D2. The channel portion CH may be disposed between the first edge portion EA1 and the second edge portion EA2. The first edge portion EA1 may come into contact with the first conductive pattern 152. The first edge portion EA1 may be electrically connected to the first conductive pattern 152. Here, the first conductive pattern 152 may refer to the bit line BL illustrated in FIG. 1. The second edge portion EA2 may come into contact with at least one data storage pattern 210 at least one of the plurality of data storage patterns 210. The second edge portion EA2 may be electrically connected to the data storage pattern 210. That is, each of the plurality of semiconductor patterns SP may be connected to a corresponding one of the plurality of data storage patterns 210.

The semiconductor pattern SP may have a first side surface F1 and a second side surface F2 facing each other in a second direction D2. The first side surface F1 may be a side surface of the first edge portion EA1, and the second side surface F2 may be a side surface of the second edge portion EA2. A first side surface F1 of the semiconductor pattern SP may be in contact with a first conductive pattern 152, and a second side surface F2 may be in contact with a data storage pattern 210.

The semiconductor pattern SP may include at least one of a single crystal semiconductor, a polycrystalline semiconductor, an oxide semiconductor, and a two-dimensional material. For example, a single crystal semiconductor may be single crystal silicon. For example, a polycrystalline semiconductor may be polysilicon. For example, the oxide semiconductor may be Indium Gallium Zinc Oxide IGZO. For example, the two-dimensional material may be MoS2, WS2, MoSe2 or WSe2. However, example embodiments are not limited thereto.

In some example embodiments, each of the first edge portion EA1 and the second edge portion EA2 of the semiconductor pattern SP may include an impurity region doped with an impurity (e.g., an n-type or p-type impurity) therein. The impurity region may form the source/drain region of the semiconductor pattern SP.

The second conductive pattern 154 is disposed on the semiconductor pattern SP and may extend in the third direction D3. The second conductive pattern 154 may surround the channel portion CH of the semiconductor pattern SP. That is, the channel portion CH may overlap with the second conductive pattern 154 in the first direction D1. For example, the second conductive pattern 154 may have a structure that surrounds the channel portion CH of the semiconductor pattern SP (e.g., a gate-all-around structure). A single second conductive pattern 154 may surround the channel portion CH of each of the semiconductor patterns SP spaced apart from each other in the third direction D3. Here, the third direction D3 may be a direction intersecting each of the first direction D1 and the second direction D2.

Each of the plurality of second conductive patterns 154 may surround a channel portion CH of a corresponding semiconductor pattern SP among the plurality of semiconductor patterns SP spaced apart from each other in the first direction D1 and may extend along the third direction D3. The second conductive patterns 154 may be spaced apart from each other in the first direction D1. The second conductive pattern 154 may refer to the word line WL illustrated in FIG. 1. The second conductive pattern 154 may include any one of TiN, MoN, Mo, Ti, and Co. However, example embodiments are not limited thereto.

A gate insulating layer GI may be disposed between the second conductive pattern 154 and the semiconductor pattern SP. A gate insulating layer GI may surround at least part of a semiconductor pattern SP. For example, a gate insulating layer GI may surround a first edge portion EA1 and a channel portion CH of a semiconductor pattern SP. The gate insulating layer GI may be provided in a plurality of layers. Each of the plurality of gate insulating layers GI may surround at least part of a corresponding semiconductor pattern SP.

The gate insulating layer GI may include at least one of silicon oxide, silicon oxynitride, and a high-k material having a dielectric constant higher than silicon oxide. The high-k material may include a metal oxide or a metal oxynitride. For example, high-k materials usable as a gate insulating layer GI may include but are not limited to, at least one of HfO2, HfSiO, HfSiON, HfTaO, HfTiO, HfZrO, ZrO2, and Al2O3. However, example embodiments are not limited thereto. A material with a high dielectric constant (high-k) may be defined as a material having a dielectric constant higher than that of silicon oxide.

An interlayer insulating film ILD may be disposed between second conductive patterns 154 adjacent to each other in the first direction D1. The second conductive patterns 154 may be spaced apart from each other in the first direction D1 by an interlayer insulating film ILD. One side surface of the interlayer insulating film ILD may be in contact with the side surface of the first conductive pattern 152. The interlayer insulating film ILD may be provided in a plurality of layers. The first stacked structure SS1 may have a structure in which a plurality of second conductive patterns 154 and a plurality of interlayer insulating films ILDs are alternately stacked in the first direction D1. The interlayer insulating film ILD may include a single film or a composite film including an insulating material.

A first spacer S1 may be disposed between interlayer insulating films ILD adjacent to each other in the first direction D1. The first spacer S1 may surround at least part of the semiconductor pattern SP. For example, the first spacer S1 may surround the first edge portion EA1 of the semiconductor pattern SP. The first spacer S1 may surround at least part of the gate insulating layer GI. One side surface of the first spacer S1 may be in contact with the side surface of the first conductive pattern 152. The first spacer S1 may be provided in plural. The first spacer S1 may include a either single film or composite film containing an insulating material.

A second spacer S2 may be disposed between interlayer insulating films ILD adjacent to each other in the first direction D1. The second spacer S2 may surround at least part of the semiconductor pattern SP. For example, the second spacer S2 may surround the second edge portion EA2 of the semiconductor pattern SP. The second spacer S2 may be provided in a plurality of pieces. The second spacer S2 may include a single film or composite film containing an insulating material.

A first insulating liner IL1 may be disposed between second spacers S2 adjacent to each other in the first direction D1. The first insulating liner IL1 may surround at least part of the semiconductor pattern SP. For example, the insulating liner IL1 may wrap the upper and lower surfaces of the second edge portion EA2 of the semiconductor pattern SP. A first insulating liner IL1 may be disposed on one side of the second spacer S2. The first insulating liner IL1 may include silicon oxide, silicon nitride, or a metal oxide having a higher dielectric constant than silicon oxide. The metal oxide may include hafnium oxide, aluminum oxide, zirconium oxide, tantalum oxide, or combinations thereof. However, example embodiments are not limited thereto. The first insulating liner IL1 may be a single-layer or multi-layer.

The first conductive pattern 152 may be disposed on the substrate 102. The first conductive pattern 152 may fill a second trench STR2 formed on the substrate 102. The first conductive pattern 152 may be disposed on a first side of the first stacked structure SS1. The first conductive pattern 152 may extend in the first direction D1. For example, the first conductive pattern 152 may be provided on the first side surface F1 of the semiconductor pattern SP. The first conductive pattern 152 may extend along the first direction D1 on the first side surface F1 of the semiconductor pattern SP. Accordingly, a single first conductive pattern 152 may contact a first side surface F1 of each of the plurality of semiconductor patterns SP spaced apart from each other in the first direction D1 and may be electrically connected to the plurality of semiconductor patterns SP.

The first conductive pattern 152 may include, but is not limited to, at least one of doped polysilicon, a metal (e.g., Al, Cu, Ti, Ta, Ru, W, Mo, Pt, Ni, Co), a conductive metal nitride (e.g., TiN, TaN, WN, NbN, TiAlN, TiSiN, TaSiN, RuTiN), a conductive metal silicide, or a conductive metal oxide (e.g., PtO, RuO2, IrO2, SRO(SrRuO3), BSRO((Ba, Sr)RuO3), CRO (CaRuO3), LSCo). The first conductive pattern 152 may include a single layer or a plurality of layers of the materials described above. In some example embodiments, the first conductive pattern 152 may include a two-dimensional material. For example, the two-dimensional material may include graphene, carbon nanotubes, or a combination thereof. However, example embodiments are not limited thereto.

The data storage pattern 210 may include a first electrode 212, a capacitor dielectric film 214 disposed on the first electrode 212, and a second electrode 216 disposed on the capacitor dielectric film 214. In some example embodiments, the semiconductor device 100 may be a dynamic random access memory (DRAM) and the data storage pattern 210 may be a capacitor. The first electrode 212 may be spaced apart from the second electrode 216 with a capacitor dielectric film 214 therebetween. In the illustrated example embodiments, the data storage pattern 210 is disclosed as a pillar-shaped structure, but the example embodiments are not limited to this example, and the data storage pattern 210 may be configured in various shapes such as a cylinder or a concave shape.

Each of the first electrode 212 and the second electrode 216 may include a conductive material. For example, each of the first electrode 212 and the second electrode 216 may include at least one of impurity-doped silicon Si, impurity-doped silicon germanium SiGe, a metal material (e.g., Ti, Mo, W, Cu, Al, Ta, Ru, Ir, Co, Pt, Au, Ag, etc.), a metal nitride (e.g., a nitride such as Ti, Mo, W, Cu, Al, Ta, Ru, Ir, Co, Pt, Au or Ag), a titanium silicon nitride (e.g., TiSiN), titanium aluminum nitride (e.g., TiAlN), and tantalum aluminum nitride (e.g., TaAlN), a conductive oxide (e.g., PtO, RuO2, IrO2, SRO(SrRuO3), BSRO((Ba, Sr)RuO3), CRO(CaRuO3), LSCo), and a metal silicide. However, example embodiments are not limited thereto. Each of the first electrode 212 and the second electrode 216 may be a single film made of a single material or a composite film including two or more materials.

For example, the capacitor dielectric film 214 may include at least one of a metal oxide such as HfO2, ZrO2, Al2O3, La2O3, Ta2O3, and TiO2, and a dielectric material having a perovskite structure such as SrTiO3(STO), (Ba, Sr)TiO3(BST), BaTiO3, PZT(lead zirconate titanate), and PLZT(lead(plomb) lanthanum zirconate titanate). However, example embodiments are not limited thereto.

In some example embodiments, the data storage pattern 210 may be a variable resistance pattern that may be switched between two resistance states by an electrical pulse. In this case, the data storage pattern DSP may include phase-change materials whose crystal state changes depending on the amount of current, perovskite compounds, transition metal oxides, magnetic materials, ferromagnetic materials, or antiferromagnetic materials. However, example embodiments are not limited thereto.

The upper insulating layer TIL may be disposed on the first stacked structure SS1. The upper insulating layer TIL may be disposed on a semiconductor pattern SP that is disposed at the top among a plurality of semiconductor patterns SP. One side of the upper insulating layer TIL may be in contact with the side surface of the first conductive pattern 152. The upper insulating layer TIL may overlap with the first stacked structure SS1 and the data storage pattern 210 in the first direction D1. The upper insulating layer TIL may include a single film or composite film containing an insulating material. For example, the upper insulating layer TIL may include silicon oxide, silicon oxynitride, or silicon nitride. However, example embodiments are not limited thereto.

The semiconductor device 100 may further include a first filling film FL1. The first filling film FL1 may be disposed on the substrate 102. The first filling film FL1 may fill the first trench STR1 formed on the substrate 102. A part of the first filling film FL1 may extend in the second direction D2 and be disposed on the data storage pattern 210. For example, the first filling film FL1 may be disposed between data storage patterns 210 that are adjacent to each other in the first direction D1. That is, the first filling film FL1 may overlap with the data storage pattern 210 in the first direction D1. Alternatively, the first filling film FL1 may overlap with the data storage pattern 210 in the second direction D2. The first filling film FL1 may overlap with the upper insulating layer TIL in the second direction D2. The first filling film FL1 may come into contact with the data storage pattern 210. The first filling film FL1 may include silicon germanium SiGe. Although the semiconductor element 100 has been described as including the first filling film FL1, the second electrode 216 is a plate electrode the first filling film FL1 may be omitted. However, example embodiments are not limited thereto.

The second cell array structure CS2 may be spaced apart from the first cell array structure CS1 in a third direction D3. The second cell array structure CS2 may be disposed on the substrate 102 along a direction perpendicular to the upper surface of the substrate 102. The second cell array structure CS2 may be disposed on a lower pattern BP formed on a substrate 102. In some example embodiments, the second cell array structure CS2 may refer to the sub-cell array SCA illustrated in FIG. 1. The second cell array structure CS2 may have the same or similar configuration as the first cell array structure CS1. Accordingly, description of the configuration overlapping with the first cell array structure CS1 is omitted. The second cell array structure CS2 may include a plurality of second stacked structures SS2. The plurality of second stacked structures SS1 may be spaced apart from the plurality of first stacked structures SS1 of the first cell array structure CS1 in the third direction D3. The second stacked structure SS2 may have the same or similar configuration as the first stacked structure SS1. Accordingly, description of the configuration of the second stacked structure SS2 that overlaps with the first stacked structure SS1 is omitted.

A support pattern 132 may be disposed on a substrate 102. The support pattern 132 may be disposed between the first stacked structure SS1 and the second stacked structure SS2. The support pattern 132 may be composed of the same material as the upper insulating layer TIL. For example, the support pattern 132 may include silicon oxide, silicon oxynitride, or silicon nitride. However, example embodiments are not limited thereto.

In some example embodiments, the data storage pattern 210 connected to the first stacked structure SS1 and the data storage pattern 210 connected to the second stacked structure SS2 may be disposed spaced apart from each other in the third direction D3. For example, a support pattern 132 may be disposed between a data storage pattern 210 connected to a first stacked structure SS1 and a data storage pattern 210 connected to a second stacked structure SS2. The data storage pattern 210 connected to the first stacked structure SS1 and the data storage pattern 210 connected to the second stacked structure SS2 may be spaced apart from each other by a desired (and/or alternatively predetermined) distance or more in the third direction D3.

In some example embodiments, the width of each of the plurality of semiconductor patterns SP in the third direction D3 may be greater than the width of each of the plurality of data storage patterns 210 in the third direction. Accordingly, the distance between the plurality of semiconductor patterns SP of the first stacked structure SS1 and the plurality of semiconductor patterns SP of the second stacked structure SS2 in the third direction D3 may be smaller than the distance between the plurality of data storage patterns 210 of the first stacked structure SS1 and the plurality of data storage patterns 210 of the second stacked structure SS2 in the third direction D3. In some example embodiments, the portion of the first stacked structure SS1 that is connected to the data storage pattern 210 may be defined as the second side of the first stacked structure SS1. Here, the width of each of the plurality of semiconductor patterns SP of the first stacked structure SS1 in the third direction D3 may decrease as it approaches the second side of the first stacked structure SS1 along the second direction D2. However, the semiconductor pattern SP may have a region where the width in the third direction D3 remains constant.

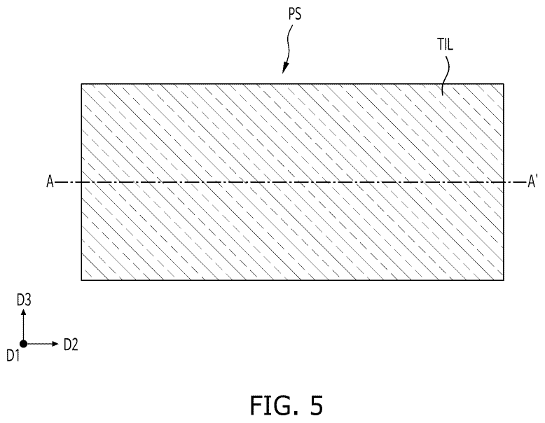

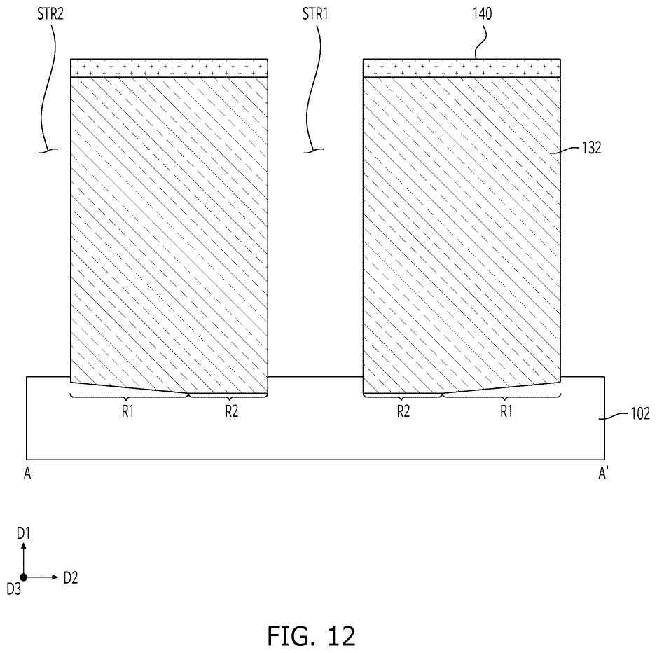

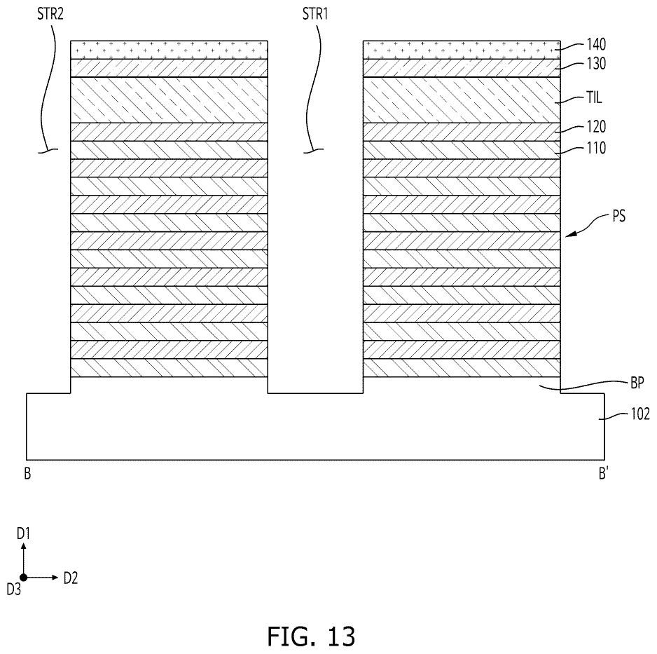

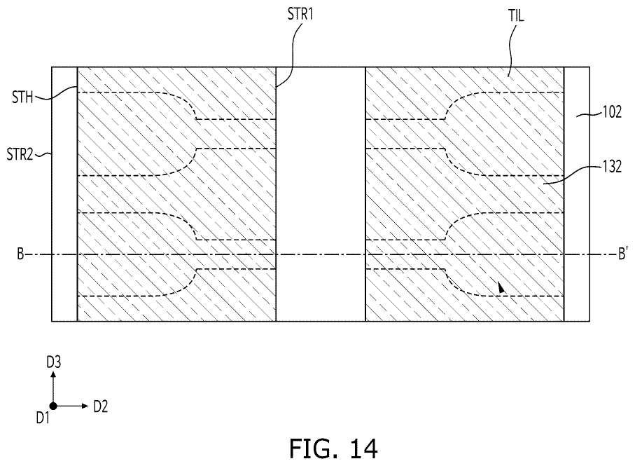

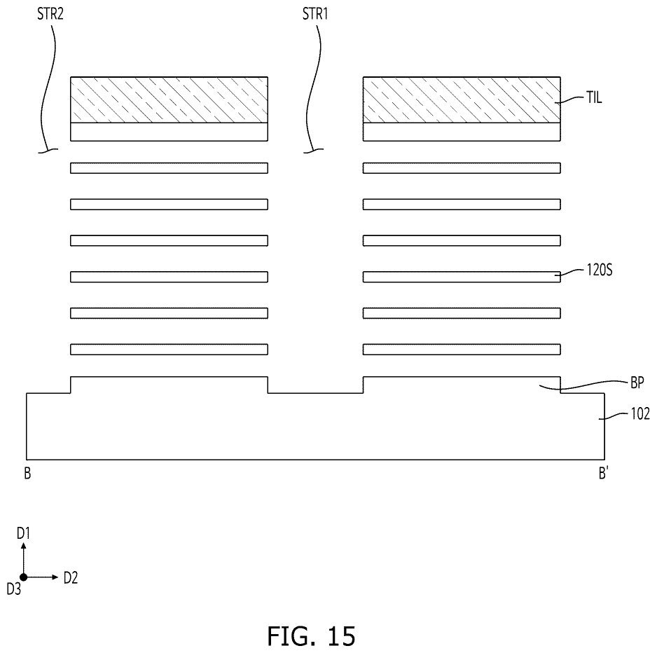

FIGS. 5 to 17 are intermediate step drawings illustrating a method of manufacturing a semiconductor device according to some example embodiments of the present disclosure. For convenience of explanation, detailed descriptions of components identical or similar to those described in detail in the embodiments disclosed in FIGS. 1 to 4 may be omitted.

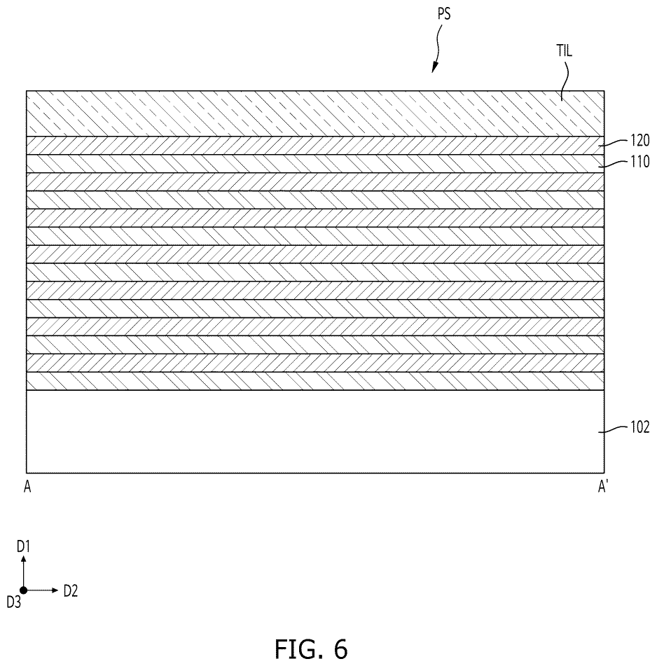

Referring to FIGS. 5 and 6, according to a method of manufacturing a semiconductor device according to some example embodiments of the present disclosure, a plurality of sacrificial layers 110 and a plurality of semiconductor layers 120 may be alternately stacked on a substrate 102 to form a pre-stacked structure PS. For example, a plurality of sacrificial layers 110 and a plurality of semiconductor layers 120 may be alternately stacked in a first direction D1 on a substrate 102. The sacrificial layer 110 may include silicon germanium SiGe, and the semiconductor layer 120 may include silicon Si. However, example embodiments are not limited thereto. A semiconductor layer 120 may be disposed on the top of the stacked structure. An upper insulating layer TIL may be further disposed on the semiconductor layer 120 disposed at the topmost position to form a preliminary stacked structure PS.

In some example embodiments, the plurality of sacrificial layers 110, the plurality of semiconductor layers 120, and the upper insulating layer TIL may be formed by chemical vapor deposition (CVD), plasma-enhanced CVD (PECVD), or atomic layer deposition (ALD). However, example embodiments are not limited thereto. In some example embodiments, each of the plurality of sacrificial layers 110 and the plurality of semiconductor layers 120 may be formed in a single crystal state using the layer in contact therewith as a seed layer or may be formed in a single crystal state through a heat treatment process. In some example embodiments, each of the plurality of sacrificial layers 110 and the plurality of semiconductor layers 120 may be formed to have substantially uniform thickness.

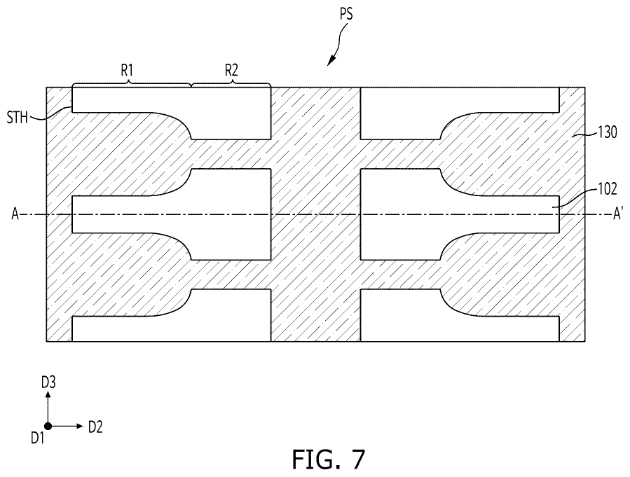

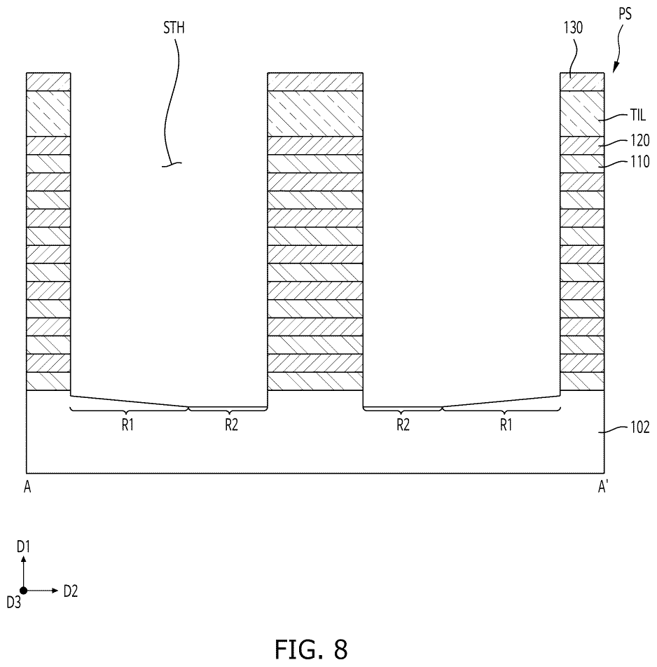

Referring to FIGS. 7 and 8, after forming a first mask layer 130 on a pre-stacked structure PS, a plurality of through holes STH that penetrate the pre-stacked structure PS and expose the substrate 102 may be formed using the first mask layer 130 as an etching mask. The first mask layer 130 may have a plurality of openings corresponding to a plurality of through holes STH. In some example embodiments, the first mask layer 130 may be composed of silicon nitride.

In some example embodiments, the stacked through holes STH may be disposed mirror-symmetrically with respect to an imaginary line extending in the third direction D3 between two adjacent stacked through holes STH along the second direction D2.

In some example embodiments, each of the plurality of through holes STH may include a first region R1 and a second region R2 extending in a second direction D2 from the first region R1. The width of the first region R1 in the third direction D3 may be smaller than the width of the second region R2 in the third direction D3. In this way, because the widths of the first region R1 and the second region R2 in the third direction D3 are different, the depth of the first region R1 in the first direction D1 may be smaller than the depth of the second region R2 in the first direction D1, as a result of etching using the first mask layer 130. In some example embodiments, the depth of the first region R1 in the first direction D1 may increase as it approaches the second region R2.

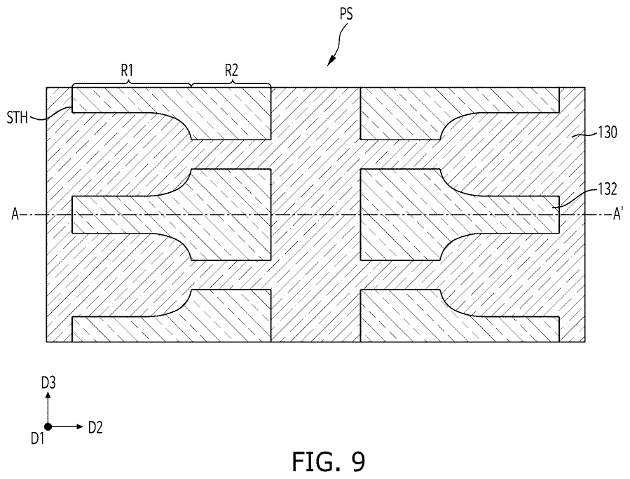

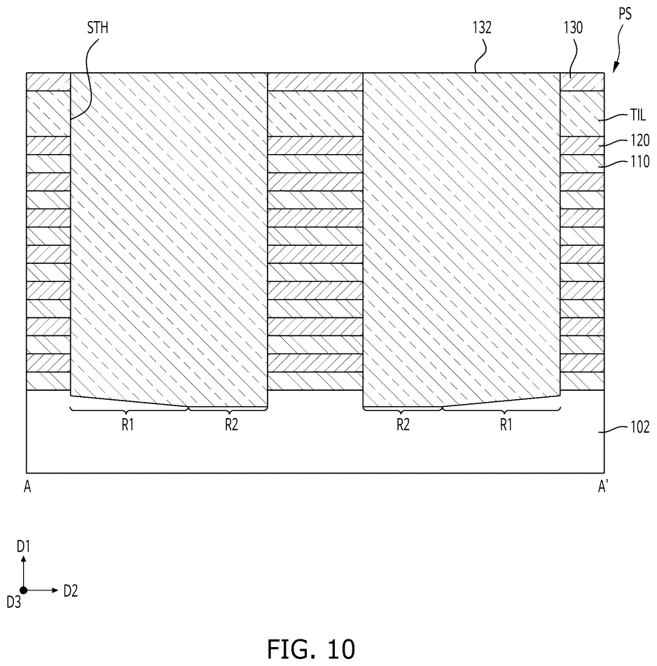

Referring to FIGS. 9 and 10, a plurality of support patterns 132 may be formed within a plurality of through holes STH. For example, a plurality of support patterns 132 may fill a plurality of through holes STH. Accordingly, each of the plurality of support patterns 132 may include a first region R1 and a second region R2 extending from the first region R1 in a second direction D2. The width of the first region R1 in the third direction D3 may be smaller than the width of the second region R2 in the third direction D3. The depth of the first region R1 in the first direction D1 may be smaller than the depth of the second region R2 in the first direction D1. In some example embodiments, the depth of the first region R1 in the first direction D1 may increase as it approaches the second region R2. A plurality of support patterns 132 may be formed by CVD, PECVD, ALD, etc. However, example embodiments are not limited thereto.

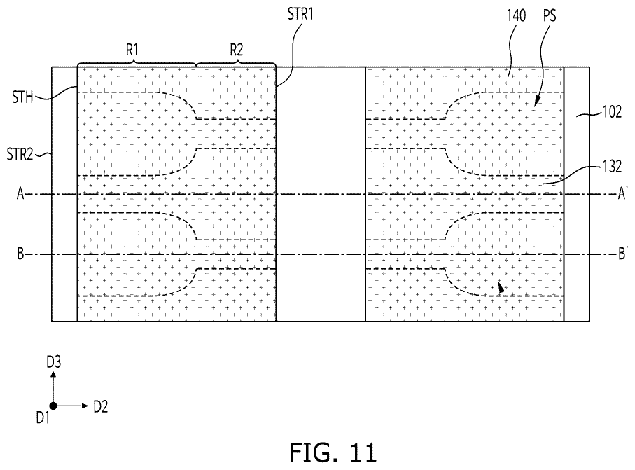

Referring to FIGS. 11 to 13, after forming a second mask layer 140 on a first mask layer 130, the second mask layer 140 may be used as an etching mask. A plurality of trenches STR1 and STR2 may be formed to expose the substrate 102 by penetrating the pre-stacked structure PS using the second mask layer 140 as an etching mask. The second mask layer 140 may have a plurality of openings corresponding to a plurality of trenches STR1 and STR2. In some example embodiments, the second mask layer 140 may be composed of silicon nitride. Here, the first trench STR1 and the second trench STR2 may be formed to penetrate at least part of the substrate. Accordingly, a lower pattern BP may be formed on the substrate 102. A pre-stacked structure PS may be disposed on the lower pattern BP.

Referring to FIGS. 11 to 15 together, a plurality of sacrificial layers 110 may be removed through the first trench STR1 and the second trench STR2. For example, the plurality of sacrificial layers 110 may be removed through an isotropic etching process having an etching selectivity with respect to the substrate 102, the plurality of semiconductor layers 120, the plurality of support patterns 132, and the upper insulating layer TIL. Next, a plurality of semiconductor bars 120S may be formed by removing a part of the plurality of semiconductor layers 120 exposed through the first trench STR1 and the second trench STR2 (for example, a thinning process for thinning the plurality of semiconductor layers 120). For example, a plurality of semiconductor bars 120S may be formed by partially removing each of a plurality of semiconductor layers 120 in the first direction D1. Here, the semiconductor layer 120 disposed at the top may not be removed. Accordingly, the width of each of the plurality of semiconductor bars 120S in the first direction D1 may be formed to have a smaller value than the width of the uppermost semiconductor layer 120 in the first direction D1.

A plurality of semiconductor bars 120S may be formed by removing a part of a plurality of semiconductor layers 120 through an isotropic etching process having an etching selectivity with respect to a plurality of support patterns 132 and an upper insulating layer TIL. Accordingly, the plurality of semiconductor bars 120S may be spaced apart from each other in the first direction D1. The plurality of semiconductor bars 120S may be supported by a plurality of support patterns 132.

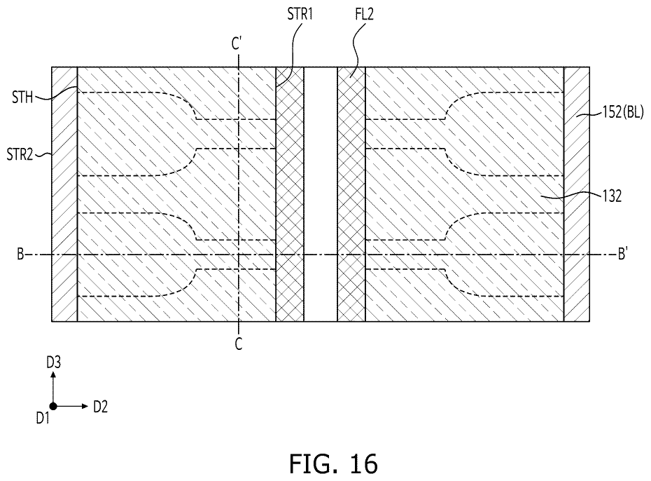

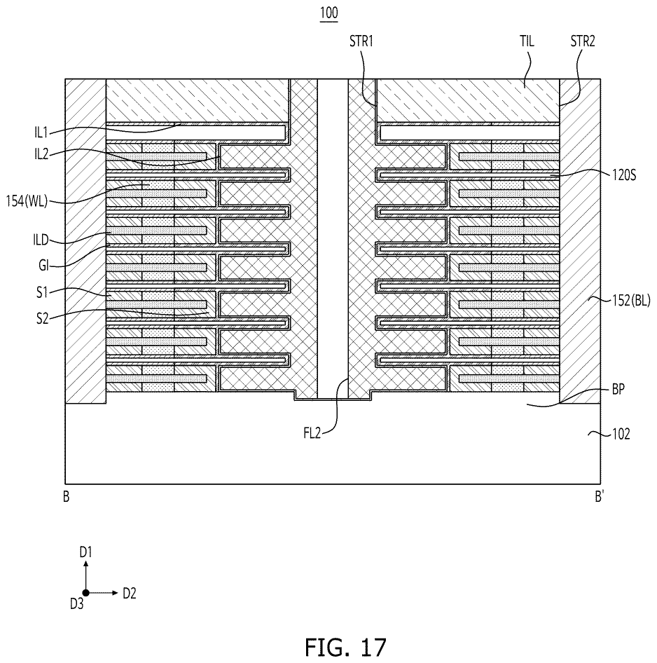

Referring to FIGS. 16 and 17, a plurality of second conductive patterns 154, a plurality of first spacers S1, and a plurality of second spacers S2 may be formed to surround at least part of a semiconductor bar 120S. Additionally, a plurality of interlayer insulating films ILDs may be formed between second conductive patterns 154 adjacent to each other in the first direction D1.

Additionally, a gate insulating layer GI, a first insulating liner IL1, and a second insulating liner IL2 may be formed to surround at least part of the plurality of semiconductor bars 120S. The second insulating liner IL2 may be disposed on the first insulating liner IL1. The second insulating liner IL2 may include silicon oxide, silicon nitride, or silicon oxynitride. However, example embodiments are not limited thereto. Further, the second filling film FL2 may fill the first through hole STR1. Additionally, the first conductive pattern 152 may fill the second through hole STR2.

In some example embodiments, the second filling film FL2 may fill at least part of the first through hole STR1. For example, as illustrated, the second filling film FL2 may not fill the central portion of the first through hole STR1. The second filling film FL2 may fill at least part of the space between a plurality of semiconductor bars 120S spaced apart from each other in the first direction D1. For example, the second filling film FL2 may overlap with a plurality of semiconductor bars 120S in the first direction D1. The second filling film FL2 may include silicon oxide, silicon nitride, or silicon oxynitride. However, example embodiments are not limited thereto. Thereafter, a part of the first insulating liner IL1, the second insulating liner IL2 and the second filling film FL2, the second part of each of the plurality of semiconductor bars 120S, etc. are removed, and then the first filling film FL1 and the data storage pattern 210 as shown in FIGS. 1 to 4 are formed, thereby forming a semiconductor device 100. Here, each of the plurality of semiconductor bars 120S may be partially removed in a second direction D2 intersecting the first direction D1 to form a data storage pattern 210.

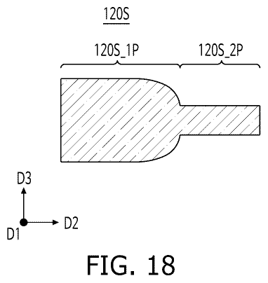

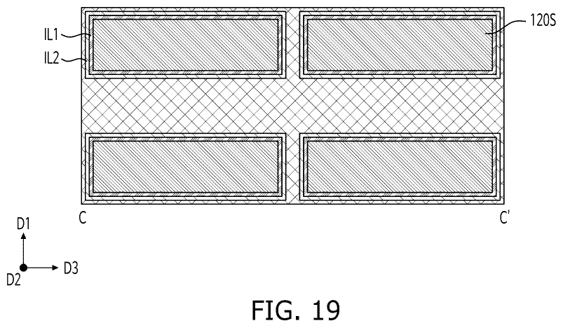

FIG. 18 is a plan view illustrating a semiconductor bar according to some example embodiments of the present disclosure. FIG. 19 is a cross-sectional view taken along line C-C′ of FIG. 16. Referring to FIG. 18, the semiconductor bar 120S may include a first part 120S_1P and a second part 120S_2P. Here, the width of the first part 120S_1P in the third direction D3 may be greater than the width of the second part 120S_2P in the third direction D3. In some example embodiments, the width of the first part 120S_1P in the third direction D3 may decrease as it approaches the second part 120S_2P. However, at least part of the first part 120S_1P may have a constant width in the third direction D3 along the second direction D2.

Referring to FIGS. 1 to 4 together, the first part 120S_1P forms a semiconductor pattern SP, and the second part 120S_2P may be substituted with a data storage pattern 210. Accordingly, the width of the semiconductor pattern SP in the third direction D3 may be larger than the width of the data storage pattern 210 in the third direction D3. Accordingly, a semiconductor device with improved electrical characteristics and/or integration density may be provided by increasing the spacing between adjacent data storage patterns in the third direction D3.

Referring to FIGS. 18 and 19 together, two semiconductor bars 120S among the plurality of semiconductor bars 120S may be spaced apart from each other in a third direction D3. Here, a support pattern 132 may be disposed between the semiconductor bars 120S. In some example embodiments, the width of the second part 120S_2P in the third direction D3 may be smaller than the width of the first part 120S_1P in the third direction D3. Accordingly, the separation distance between the second parts 120S_2P adjacent to each other in the third direction D3 may be greater than the separation distance between the first parts 120S_1P. Accordingly, the first insulating liners IL1 surrounding each of the second parts 120S_2P adjacent to each other in the third direction D3 may be spaced apart in the third direction D3. Additionally, the second insulating liners IL2 surrounding each of the second parts 120S_2P adjacent to each other in the third direction D3 may be spaced apart from each other in the third direction D3. Accordingly, a semiconductor device with improved electrical characteristics and/or integration level may be provided.

Although the present disclosure has been described above by means of limited example embodiments and drawings, the present disclosure is not limited thereto, and various modifications and variations are possible by those skilled in the art within the scope of the technical idea of the present disclosure and the equivalent scope of the patent claims to be described below.

1. A semiconductor device comprising:
a substrate;
a first stacked structure comprising a plurality of semiconductor patterns on the substrate, the plurality of semiconductor patterns stacked and spaced apart from each other in a first direction;
a first conductive pattern on a first side of the first stacked structure and extending in the first direction; and
a plurality of data storage patterns on a second side of the first stacked structure, the plurality of data storage patterns spaced apart from each other in the first direction, and extending in a second direction, the second direction intersecting the first direction,
wherein a width of each of the plurality of semiconductor patterns in a third direction is greater than a width of each of the plurality of data storage patterns in the third direction, the third direction intersecting each of the first direction and the second direction.

2. The semiconductor device as claimed in claim 1, wherein the width of each of the plurality of semiconductor patterns in the third direction decreases toward the second side of the first stacked structure along the second direction.

3. The semiconductor device as claimed in claim 1, further comprising:
a second stacked structure on the substrate, the second stacked structure spaced apart from the first stacked structure in the third direction; and
a support pattern between the first stacked structure and the second stacked structure.

4. The semiconductor device as claimed in claim 3, wherein
the support pattern comprises a first region and a second region, the second region extending from the first region in the second direction, and
a depth of the first region in the first direction is smaller than a depth of the second region in the first direction.

5. The semiconductor device as claimed in claim 4, wherein the depth of the first region in the first direction increases toward the second region.

6. The semiconductor device as claimed in claim 4, wherein
the first region overlaps the plurality of semiconductor patterns in the third direction, and
the second region overlaps the plurality of data storage patterns in the third direction.

7. The semiconductor device as claimed in claim 1, wherein each of the plurality of semiconductor patterns is connected to a corresponding data storage pattern among the plurality of data storage patterns.

8. The semiconductor device as claimed in claim 1, further comprising:
a filling film on the plurality of data storage patterns,
wherein each of the plurality of data storage patterns comprises
a first electrode,
a capacitor dielectric film on the first electrode, and
a second electrode on the capacitor dielectric film.

9. The semiconductor device as claimed in claim 1, wherein each of the plurality of semiconductor patterns comprises:
a first edge portion in contact with the first conductive pattern;
a second edge portion in contact with one of the plurality of data storage patterns; and
a channel portion between the first edge portion and the second edge portion.

10. The semiconductor device as claimed in claim 9, further comprising:
a second conductive pattern on each of the plurality of semiconductor patterns and extending in the third direction,
wherein the channel portion overlaps the second conductive pattern in the first direction.

11. The semiconductor device as claimed in claim 1, wherein
a thickness in the first direction of an uppermost semiconductor pattern at an uppermost position among the plurality of semiconductor patterns is greater than a thickness in the first direction of remaining semiconductor patterns among the plurality of semiconductor patterns.

12. A semiconductor device comprising:
a substrate;
a first stacked structure comprising a plurality of semiconductor patterns on the substrate, the plurality of semiconductor patterns stacked and spaced apart from each other in a first direction;
a first conductive pattern on a first side of the first stacked structure and extending in the first direction;
a plurality of data storage patterns on a second side of the first stacked structure, the plurality of data storage patterns spaced apart from each other in the first direction and extending in a second direction, the second direction intersecting the first direction;
a second stacked structure on the substrate and spaced apart from the first stacked structure in a third direction, the third direction intersecting each of the first direction and the second direction; and
a support pattern between the first stacked structure and the second stacked structure,
wherein the support pattern comprises a first region and a second region, the second region extending from the first region in the second direction, and
a depth of the first region in the first direction is smaller than a depth of the second region in the first direction.

13. The semiconductor device as claimed in claim 12, wherein the depth of the first region in the first direction increases toward the second region.

14. The semiconductor device as claimed in claim 12, wherein a width of each of the plurality of semiconductor patterns in the third direction is greater than a width of each of the plurality of data storage patterns in the third direction.

15. The semiconductor device as claimed in claim 14, wherein the width of each of the plurality of semiconductor patterns in the third direction decreases toward the second side of the first stacked structure along the second direction.

16. The semiconductor device as claimed in claim 12, wherein
the first region overlaps the plurality of semiconductor patterns in the third direction, and
the second region overlaps the plurality of data storage patterns in the third direction.

17. The semiconductor device as claimed in claim 12, wherein each of the plurality of semiconductor patterns is connected to a corresponding data storage pattern among the plurality of data storage patterns.

18. The semiconductor device as claimed in claim 12, wherein each of the plurality of semiconductor patterns comprises:
a first edge portion contacting the first conductive pattern;
a second edge portion contacting one of the plurality of data storage patterns; and
a channel portion between the first edge portion and the second edge portion.

19. The semiconductor device as claimed in claim 18, further comprising:
a second conductive pattern on each of the plurality of semiconductor patterns, the second conductive pattern extending in the third direction,
wherein the channel portion overlaps the second conductive pattern in the first direction.

20. A semiconductor device comprising:
a substrate;
a first stacked structure comprising a plurality of semiconductor patterns on the substrate, the plurality of semiconductor patterns stacked and spaced apart from each other in a first direction;
a first conductive pattern on a first side of the first stacked structure and extending in the first direction;
a plurality of data storage patterns on a second side of the first stacked structure, the plurality of data storage patterns spaced apart from each other in the first direction and extending in a second direction, the second direction intersecting the first direction;
a second stacked structure on the substrate, the second stacked structure spaced apart from the first stacked structure in a third direction, the third direction intersecting each of the first direction and the second direction; and
a support pattern between the first stacked structure and the second stacked structure,
wherein
a width of each of the plurality of semiconductor patterns in the third direction is greater than a width of each of the plurality of data storage patterns in the third direction,
the width of each of the plurality of semiconductor patterns in the third direction decreases toward the second side of the first stacked structure along the second direction,
the support pattern comprises a first region and a second region, the second region extending from the first region in the second direction, and
a depth of the first region in the first direction is smaller than a depth of the second region in the first direction.
